(19) United States
(12) Patent Application Publication
(10) Pub. No.: US 2009/0322324 A1
(43) Pub. Date: Dec. 31, 2009

(54) GEOMETRIES FOR SUPERCONDUCTING SENSING COILS FOR SQUID-BASED SYSTEMS

(76) Inventors: Konstantin I. PENANEN, Glendale, CA (US); Byeong H. Eom, Pasadena, CA (US); Inseob Hahn, La Crescenta, CA (US)

Correspondence Address: Steinfl & Bruno, 301 N Lake Ave Ste 810, Pasadena, CA, 91101, US

(21) Appl. No.: 12/113,163

(22) Filed: Apr. 30, 2008

Related U.S. Application Data
(60) Provisional application No. 60/927,706, filed on May 4, 2007.
(60) Provisional application No. 61/072,897, filed on Apr. 3, 2008.

(51) Int. Cl. G01R 33/02

(52) U.S. Cl. 324/248

(57) ABSTRACT

Geometries for superconducting sensing coils for SQUID-based systems are described, such as a superconducting sensing coil with a flat washer shape the inner diameter of which has an extension which is a small fraction of the extension of the outer diameter. Also described are a second-order gradiometer comprising such coils and a superconducting sensing coil structure comprising an external low-melting point metallic loop encapsulating one or more superconductive coil loops, together with a heterogeneous superconductive sensing wire for gradiometers, consisting of an internal copper skeleton surrounded by an external lead-tin alloy.

### CROSS-REFERENCE TO RELATED APPLICATIONS

This application claims priority to U.S. Provisional Application 60/927,706 filed on May 4, 2007 and U.S. Provisional Application Ser. No. 61/072,897 for “Heterogeneous Construction For Superconducting Low-Noise Sensing Coils” by Inseob Hahn, Konstantin I. Penanen and Byeong H. Eom, Docket No. CIT-5120-P filed on Apr. 3, 2008, the contents of both of which are incorporated herein by reference in their entirety. The present application may be related to U.S. patent application Ser. No. ______ (not yet assigned) for “Low Field SQUID MRI Devices, Components and Methods” by by Inseob Hahn, Konstantin I. Penanen and Byeong H. Eom, Docket No. P184-US, filed on the same date of the present application, the contents of which are also incorporated by reference in their entirety.

### STATEMENT OF GOVERNMENT GRANT

The invention described herein was made in the performance of work under a NASA contract, and is subject to the provisions of Public Law 96-517 (35 USC 202) in which the Contractor has elected to retain title

### FIELD

The present disclosure relates to sensing coils for superconducting quantum interference device- (SQUID-) based systems. More in particular, it relates to geometries for superconducting sensing coils for SQUID-based systems.

### BACKGROUND

Gradiometers used in SQUID low field magnetic resonance imaging (MRI) systems and SQUID magneto-encephalography (MEG) are known. See, for example, U.S. Pat. No. 5,049,818. The wire coils of such applications are made of superconductive material and are usually placed on a non-magnetic cylindrical carrier body.

The resolution and the acquisition time in low-field MRI are limited by the noise-equivalent sensitivity of the sensing coils. When coupled with a SQUID sensor, the coil sensitivity is in turn limited by the geometry (coil size and distance from the signal source) and by the coil self-inductance.

It is helpful to decrease the coil self-inductance while maintaining the coil effective size. An advantage of this is that one is allowed to wind a larger amount of turns while maintaining the impedance match with the SQUID sensor. Currently, the coils are typically wound with a small diameter (75-150 micron) superconducting wire in a gradiometer or second-order gradiometer geometry, i.e. +1, −2, +1 windings, where the sign indicates the relative current direction.

### SUMMARY

According to a first aspect, a superconducting sensing coil for a SQUID-based apparatus is provided, the superconducting sensing coil having a flat washer shape defining an inner diameter (ID) and an outer diameter (OD), the inner diameter having an extension which is less than 90% of an outer diameter extension.

According to a second aspect, a superconducting sensing coil structure for a SQUID-based apparatus is provided, the superconducting sensing coil structure comprising an external point superconducting metallic loop encapsulating one or more superconductive coil loops.

According to a third aspect, a heterogeneous superconductive sensing wire for gradiometers is provided, consisting of an internal highly thermally conducting but not electrically superconducting skeleton surrounded by an external superconducting material.

Further embodiments of the present disclosure are shown in the written specification, drawings and claims of this application.

The Applicants have noted that in a geometry where the coil of the present disclosure is wound with the same number of turns, occupies similar space, and has similar sensitivity range, the inductance of such coil is reduced by approximately 30% compared to a coil wound with 125 micron wire. Stated in a different manner, the number of turns in such coil can be increased by about 50% corresponding to a sensitivity increase of about 50%. The increase in Signal-to-Noise Ratio (SNR) by 50% is equivalent to reducing the MRI acquisition time by half.

### BRIEF DESCRIPTION OF THE DRAWINGS

FIG. 1A shows a top view of a washer structure useful to explain the concepts of the present disclosure.

FIG. 1B shows a sectional view of the washer structure of FIG. 1A.

FIG. 2 shows a top view of a washer-like gradiometer coil in accordance with the present disclosure.

FIG. 3 shows a cross-sectional view of the axially-symmetric field profile generated by a second-order gradiometer in accordance with the present disclosure.

FIG. 4A is a perspective view showing a first type of connection between lead wires and gradient coil washer-like structures.

FIG. 4B is a perspective view showing a second type of connection between lead wires and gradient coil washer-like structures.

FIG. 5 is a cutout perspective view showing a loop structure encapsulating a thin superconductive wire loop.

FIG. 6 shows a cross-sectional view of a heterogeneous superconductive wire according to a further embodiment of the present disclosure.

### DETAILED DESCRIPTION

In order to analyze the relative performance of input or sensing coils for SQUID-based systems such as SQUID MEG and SQUID MRI, two parameters have to be evaluated: sensitivity to a suitably located elementary dipole and coil inductance. The sensitivity, through a reciprocity relation, is proportional to the magnitude of the field generated by the coil carrying a unit current at the location of the dipole. The self-inductance of the coil is proportional to the integral of the square of the magnetic field. Both sensitivity and self-inductance can be evaluated numerically, taking into consideration the geometrical constraints of the structure where the input coils are located. The desire is that of maximizing the sensitivity while minimizing the self-inductance of the coil.

It is advantageous to place a sample or subject as close to the input coil as possible. Since the coil is cryogenically cooled, and the sample is at room temperature, the space occupied by the coil is enclosed in a cryogenic shield. This geometry puts constraints on the shape of the coil.

The self-inductance of a single superconductive loop of radius r and wire radius ρ can be described for large r by

$${L}_{loop} = {μ}_{0} r ( ln \frac{8 r}{ρ} - 2 ) ,$$

where μ₀ is the permeability of vacuum. On the other hand, the loop sensitivity depends primarily on r and varies slowly with ρ. Therefore, if a given sensitivity is desired to be maintained, ρ should be slowly increased for the self-inductance to decrease. Such effect should be balanced out with a competing effect, i.e. that a thicker wire (i.e. higher value of ρ) will extend out further. Given that the coil assembly is limited by the cryogenic shield, the coil assembly will then have to be moved further from the sample, thus reducing the sensitivity.

Therefore, replacing the circular cross-section wire coil with appropriately shaped wire with larger effective diameter can reduce the coil inductance. In the case of sensing coils for SQUID MRI and SQUID MEG, additional constraints are set by the desired range of the sensor, the size limitations of the cryogenically cooled space, and the practical limitation of having the coil external to the cylindrical body.

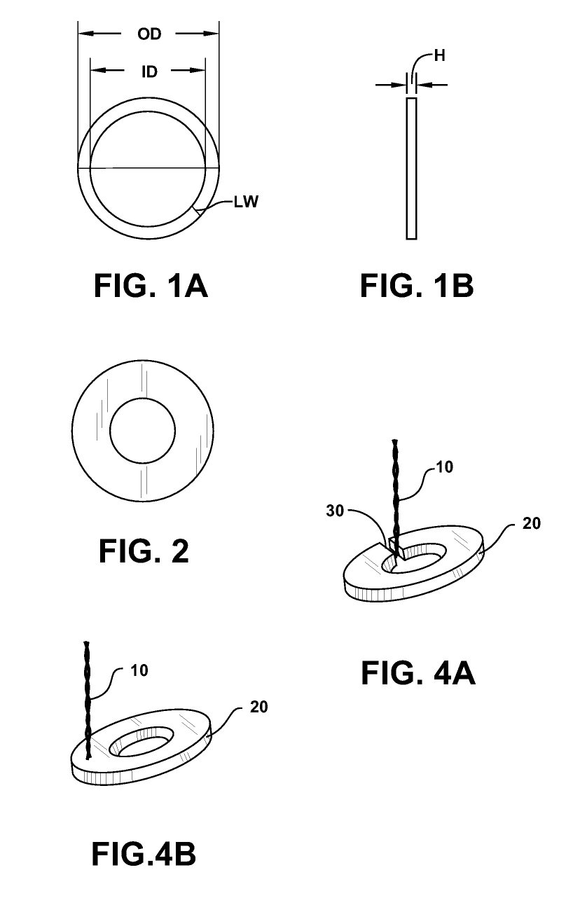

In view of the above observations and constraints, applicants have noted that the optimal shape of individual loops for both SQUID MEG and SQUID MRI, and similar sensing configurations where the signal from small magnetic dipoles is detected, is that of a thin superconductor washer, where the meaning of thin will be better explained with reference to FIG. 1B below.

FIGS. 1A and 1B show a top view and a sectional view of a washer structure, which can be defined by an inner (empty) diameter ID, an outer diameter OD, and a height H. Each washer structure also defines a loop width LW, with LW=(OD−ID)/2.

In accordance with the teachings of the present disclosure, the loop width LW is made comparable to the overall size (OD/2). In other words, (OD−ID) is made a significant fraction of OD, preferably (OD−ID)> 1/10 OD. Therefore, the wire coil shape in accordance with the present disclosure is much similar to the one shown in FIG. 2 than the one shown in FIG. 1A. This is in contrast with wire sizes currently used in SQUID MRI and MEG where the loop width is substantially smaller than OD, usually of a factor of more than 10.

The applicants have also noted that the thickness H (see FIG. 1B) of the wire coil can be at least smaller than the loop width LW. Moreover, the cross section of the wire coils does not need to be rectangular or circular, as such cross-sectional shapes do not significantly influence sensitivity and self-inductance. For example, in case of a flat bottom cryogenic enclosure, a low profile washer shape (H<LW/10) is preferable.

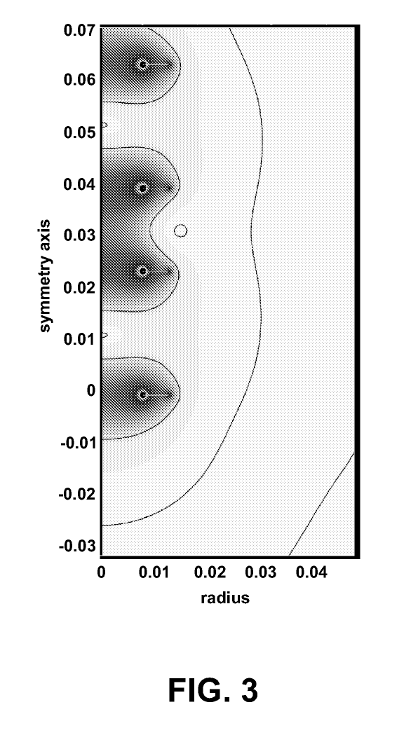

The applicants have also noted that in the second-order gradiometer arrangements with (+1, −2, +1) windings, separation of the middle windings is preferred, thus forming a (+1, −1, −1, +1) washer-like coil structure. In particular, such four-washer arrangement further reduces the self-inductance of the coil. An example of field profile generated by four washers arranged in a second-order (+1, −1, −1, +1) gradiometer is shown in FIG. 3. As usual, the (+) sign means counterclockwise, the (−) sign means clockwise and the number after the sign represents the number of loops. Preferably, the spacing between the two washer-like structures of the (−1, −1) middle loops can be larger than (OD−ID)/2.

The gradiometer wire coils are connected with superconducting lead wires (e.g. Nb or NbTi wires) leading to the SQUID. FIGS. 4A and 4B show possible embodiments of connections of lead wires (10) to the washer-like wire coil arrangement of the present disclosure. In the embodiment of FIG. 4A, washer-like loop (20) has a slit (30), allowing contact of one of the lead wires to one side of the loop (20) and contact of the other lead wire to another side of the coil (30). The gap or slit (30) prevents formation of a shorting path in parallel with the leads, so that all the current is directed into the leads. The gap or slit (30) should be much smaller than the dimension of the wire cross section. According to such embodiment, the lead wires (10) are embedded into the loop (20). A further embodiment is shown in FIG. 4B, where lead wires (10) are connected to the loop (20) either by way of bonding or by way of concurrent machining with the loop (20).

In the embodiment shown in FIGS. 2, 3, 4A and 4B, the wire coil structure forms the superconductive loop (20). However, a large superconductive wire, for example >0.020 inches, can sometimes be of limited practical use especially when a persistent-current current loop enclosing a remotely placed SQUID is desired. Bonding a thicker wire used for the sensor is a possibility, but a reliable superconducting connection to a different material may not be easily achievable. In particular, in the case of a thin sensing coil wire, wires of the same material (e.g., Nb or NbTi) can be used for the sensing coil and the leads. They can be a continuous single wire or be easily bonded. However, if a large cross section sensing wire is used, it is not practical to make it of the same material as that of the leads.

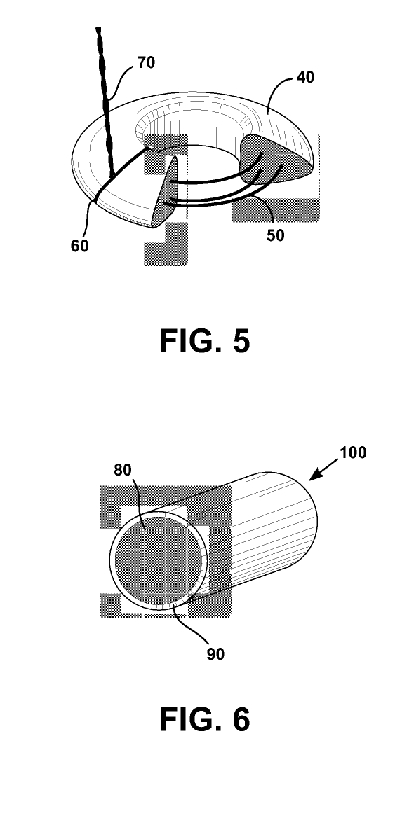

According to a further embodiment of the present disclosure, a loop structure can be provided that encapsulates a thin superconductive wire loop, as shown in the perspective view of FIG. 5. For example, the size of the Nb or NbTi wires can be <about 0.020 inches.

The shape of the outside loop structure of FIG. 5 can differ. Such shape depends on the geometric constraint of the cryogenic enclosure and the imaging object. In case of a flat bottom cryogenic enclosure, a flat washer shape is generally optimal to maximize sensitivity and to minimize the self-inductance.

In particular, FIG. 5 shows a perspective view of a loop structure (40) encapsulating a coil loop (50), shows by way of a cutout section. In the embodiment of FIG. 5, coil loop (50) is a single wire with three turns. Also shown in FIG. 5 is a slit (60) to allow contact between the wires of the coil loop (50) and the lead wires (70). Loop structure (40) is a low-melting point metal (e.g., Indium, Lead, or Lead-Tin alloy) wire loop having a large diameter circular cross section (see, e.g., the previous embodiment), or another specific shape, appropriate for the application. The low-melting point (e.g., <330° C., Pb melting point and more generally temperatures compatible with the embedded wires and their insulation) allows to easily cast a big shape without affecting the embedded wires. Loop structure (40) can be formed on the coil loop (50) to encapsulate it by way of melting. Slit (60) is a small vacuum or insulating material gap to avoid shorting if the lead wire is not insulated. In some embodiments, more than one slit can be optionally provided.

The higher the self-inductance and sensitivity required, the higher the number of thin wire loops that can be embedded inside the molded loop (40). In such case, the thin superconducting wires should be insulated.

The loop structure (40) should preferably be compatible with molding and/or shaping fabrication on the one or more superconductive coil loops.

The above embodiments can be applied to magnetic probes for SQUID MRI devices, SQUID MEG devices and other similar biological magnetic probes, e.g., any superconducting magnetometer application, including MRI, MEG (magneto-encephalography), EPR (electron paramagnetic resonance), susceptometry and so on.

According to yet another embodiment of the present disclosure, a superconducting gradiometer sensing wire having heterogeneous composition is disclosed.

In particular, FIG. 6 shows a cross-sectional view of the heterogeneous superconductive wire according to this embodiment, comprising an internal copper skeleton (80) coated with a lead-tin (Sn—Pb) alloy (90). By way of this combination of materials, a high thermal conductance, superconductive wire is obtained, where the current passes through the external superconductive layer (90) and thermal conduction occurs by way of the internal copper skeleton or rod (80). By way of example, applicants used copper having a 3.2 mm diameter. However, any thickness, and in particular a thickness larger that about 0.020 inches would benefit. Thinner coils can be wound with Nb or Nb/Ti. As to a Sn—Pb layer, in order to obtain superconducting shielding, a thickness of several microns or more is preferable. Although copper is preferred as it is a very good thermal conductor, also gold or aluminum can be used if a low-melting superconductor layer can be deposited without forming gold alloys. Also other combinations are possible.

In particular, because the superconductive coating (90) shields the thermal Johnson noise from the copper skeleton (80), the composite sensing coil (100) retains a low-noise performance. Superior thermal conductivity of the copper skeleton (80) allows for shorter initial cool-down time, and allows the temperature of the sensing coil (100) to remain below the superconducting transition of the lead-tin alloy (90) in the presence of a moderate radiative thermal load, e.g., less than about 10 mW.

One of the uses of the superconducting gradiometer sensing wire having heterogeneous composition shown above is in cryogen-free (i.e. cryocooler-based) compact magnetic resonance imaging medical diagnostic systems. Additionally, this type of superconducting coil system can also be used for other cryogenic magnetometry applications.

Accordingly, what has been shown are geometries for superconductive sensing coils for SQUID-based systems. While these superconductive sensing coils have been described by means of specific embodiments and applications thereof, it is understood that numerous modifications and variations could be made thereto by those skilled in the art without departing from the spirit and scope of the disclosure. It is therefore to be understood that within the scope of the claims, the disclosure may be practiced otherwise than as specifically described herein.

1. A superconducting sensing coil for a SQUID-based apparatus, the superconducting sensing coil having a flat washer shape defining an inner diameter (ID) and an outer diameter (OD), the inner diameter having an extension which is less than 90% of an outer diameter extension.

2. The superconducting sensing coil of claim 1, wherein (OD−ID)/2 defines a loop width (LW) of the superconducting sensing coil, and wherein the superconducting sensing coil has a thickness H smaller than LW.

3. The superconducting sensing coil of claim 2, wherein H is less than LW/10.

4. The superconductive sensing coil of claim 1, comprising a gap region.

5. A second-order gradiometer comprising a plurality of superconductive sensing coils in accordance with claim 1.

6. The second-order gradiometer of claim 5, wherein the plurality of superconductive sensing coils are three sensing coils in a (+1, −2, +1) arrangement.

7. The second-order gradiometer of claim 5, wherein the plurality of superconductive sensing coils are four sensing coils in a (+1, −1, −1, +1) arrangement.

8. The second-order gradiometer of claim 7, wherein a distance between middle coils of the second-order gradiometer is larger than a loop width of the middle coils.

9. A SQUID-based apparatus comprising one or more superconducting sensing coils in accordance with claim 1, each superconductive sensing coil being connected to lead wires leading to a SQUID.

10. The SQUID-based apparatus of claim 9, wherein the lead wires are bonded to the respective superconductive sensing coil.

11. The SQUID-based apparatus of claim 9, wherein the lead wires are machined together with the respective superconductive sensing coil.

12. The SQUID-based apparatus of claim 9, wherein each superconductive sensing coil comprises a gap, the lead wires being connected to the respective superconductive sensing coil inside the gap.

13. A superconducting sensing coil structure for a SQUID-based apparatus, the superconducting sensing coil structure comprising an external point superconducting metallic loop encapsulating one or more superconductive coil loops.

14. The superconducting sensing coil structure of claim 13, wherein the superconducting metallic loop is compatible with molding and/or shaping fabrication on the one or more superconductive coil loops.

15. The superconducting sensing coil structure of claim 13, wherein the external low-melting point metallic loop comprises a slit region, adapted for connection to lead wires leading to the SQUID.

16. A heterogeneous superconductive sensing wire for gradiometers, consisting of an internal highly thermally conducting but not electrically superconducting skeleton surrounded by an external superconducting material.

17. The heterogeneous superconductive sensing wire of claim 16, wherein the internal skeleton is a copper skeleton.

18. The heterogeneous superconductive sensing wire of claim 16, wherein the internal skeleton is a gold or aluminum skeleton.

19. The heterogeneous superconductive sensing wire of claim 16, wherein the external superconducting material is selected from Nb, Nb/Ti and Sn—Pb.
